(19) United States
(12) Patent Application Publication
(10) Pub. No.: US 2008/0236795 A1
(43) Pub. Date: Oct. 2, 2008

(54) LOW-PROFILE HEAT-SPREADING LIQUID CHAMBER USING BOILING

(76) Inventors: Seung Mun You, Arlington, TX (US); Joo Han Kim, Arlington, TX (US); Sang M. Kwark, Grand Prairie, TX (US); Jesse Jaejin Kim, Sunnyvale, CA (US)

Correspondence Address: TRAN & ASSOCIATES, 6768 MEADOW VISTA CT., SAN JOSE, CA, 95135, US

(21) Appl. No.: 11/690,937

(22) Filed: Mar. 26, 2007

(51) Int. Cl. H05K 7/20

(52) U.S. Cl. 165/104.21; 361/700

(57) ABSTRACT

Systems and fabrication methods are disclosed for a heat spreader to cool a device. The heat spreader has first and second opposing proximal surfaces defining a chamber having a liquid therein; and one or more structures mounted in the chamber to induce a liquid flow pattern during a boiling of the liquid to distribute heat.

### BACKGROUND

The invention relates to a heat spreader with liquid boiling to provide heat transfer.

Continual advances in semiconductor technology have driven significant increases in the density as well as the speed at which processors and other electronic components can operate. A side effect of these technological advances is that state-of-the-art processors and other integrated circuits produce significantly more heat during normal operation than their predecessors.

High-heat-flux and high-power microelectronic devices require the development of innovative and efficient heat spreader that can provide uniform temperature distribution over wider flat surface. Conventionally, a heat spreader is used for effectively dissipating the heat generated by a semiconductor device. Conventional heat spreaders typically use a solid block of high thermal conductivity (such as copper, aluminum, and graphite). The heat spreaders are thermally connected to heat sinks which serve as heat-releasing members.

One cooling technology is the heat pipe. A heat pipe includes a sealed envelope that defines an internal chamber containing a capillary wick and a working fluid capable of having both a liquid phase and a vapor phase within a desired range of operating temperatures. When one portion of the chamber is exposed to relatively high temperature it functions as an evaporator section. The working fluid is vaporized in the evaporator section causing a slight pressure increase forcing the vapor to a relatively lower temperature section of the chamber, which functions as a condenser section. Heat pipes are designed to evaporate and not to boil since boiling is well known as a limiting factor for most of the heat pipes. The vapor is condensed in the condenser section and returns through the capillary wick to the evaporator section by capillary pumping action. Because a heat pipe operates on the principle of phase changes rather than on the principles of conduction or convection, a heat pipe is theoretically capable of transferring heat with lower thermal resistance than conduction heat transfer systems. Consequently, heat pipes have been utilized to cool various types of high heat-producing apparatus, such as electronic equipment (See, e.g., U.S. Pat. Nos. 3,613,778; 4,046,190; 4,058,299; 4,109,709; 4,116,266; 4,118,756; 4,186,796; 4,231,423; 4,274,479; 4,366,526; 4,503,483; 4,697,205; 4,777,561; 4,880,052; 4,912,548; 4,921,041; 4,931,905; 4,982,274; 5,219,020; 5,253,702; 5,268,812; 5,283,729; 5,331,510; 5,333,470; 5,349,237; 5,409,055; 5,880,524; 5,884,693; 5,890,371; 6,055,297; 6,076,595; and 6,148,906 and 7,124,809).

The flow of the vapor and the capillary flow of liquid within a heat pipe are both produced by pressure gradients that are created by the interaction between naturally-occurring pressure differentials within the heat pipe. These pressure gradients eliminate the need for external pumping of the system fluids. In addition, the existence of liquid and vapor in equilibrium, without noncondensable gases, results in higher thermal efficiencies. In order to increase the efficiency of heat pipes, various wicking structures have been developed in the prior art to promote liquid transfer between the condenser and evaporator sections as well as to enhance the thermal transfer performance between the wick and its surroundings. They have included longitudinally disposed parallel grooves and the random scoring of the internal pipe surface. In addition, the prior art also discloses the use of a wick structure which is fixedly attached to the internal pipe wall. The compositions and geometries of these wicks have included a uniform fine wire mesh and sintered metals. Sintered metal wicks generally comprise a mixture of metal particles that have been heated to a temperature sufficient to cause fusing or welding of adjacent particles at their respective points of contact. The sintered metal powder then forms a porous structure with capillary characteristics. Although sintered wicks have demonstrated adequate heat transfer characteristics in the prior art, the minute metal-to-metal fused interfaces between particles tend to constrict thermal energy conduction through the wick. This has limited the usefulness of sintered wicks in the art.

The wick is, in short, a member for creating capillary pressure, and therefore, it is preferable that it be excellent in hydrophilicity with the working fluid, and it is preferable that its effective radius of a capillary tube as small as possible at a meniscus formed on a liquid surface of the liquid phase working fluid. Accordingly, a porous sintered compound or a bundle of extremely thin wires generally is employed as a wick. Among those wick members according to the prior art, the porous sintered compound may create great capillary pressure (i.e., a pumping force to the liquid phase working fluid) because the opening dimensions of its cavities are smaller than that of other wicks. Also, the porous sintered compound may be formed into a sheet shape so that it may be employed easily on a flat plate type heat pipe or the like, called a vapor chamber, which has been attracting attention in recent days. Accordingly, the porous sintered compound is a preferable wick material in light of those points of view.

As discussed in U.S. Pat. No. 7,137,442 ('442 patent), it is possible to increase the capillary pressure for refluxing the liquid phase working fluid if a porous body is employed as a wick to be built into the heat pipe. This is advantageous for downsizing the vapor chamber. However, a flow path is formed by the cavity created among the fine powders as the material of a porous body, so that the flow cross-sectional area of the flow path has to be small and as intricate as a maze. Therefore, it is possible to enhance the capillary pressure which functions as the pumping force for refluxing the liquid phase working fluid to a portion where it evaporates. However, on the other hand, there is a disadvantage because the flow resistance against the liquid phase working fluid is relatively high. For this reason, if the input amount of heat from outside increases suddenly and drastically, for example, the wick may dry out due to a shortage of the liquid phase working fluid to be fed to the portion where the evaporation of the working fluid takes place. The '442 patent discloses A vapor chamber, in which a condensable fluid, which evaporates and condenses depending on a state of input and radiation of a heat, is encapsulated in a hollow and flat sealed receptacle as a liquid phase working fluid; and in which the wick for creating the capillary pressure by moistening by the working fluid is arranged in said sealed receptacle, comprising: a wick for creating a great capillary pressure by being moistened by said working fluid, which is arranged on the evaporating part side where the heat is input from outside; and a wick having a small flow resistance against the moistening working fluid, which is arranged on the condensing part side where the heat is radiated to outside.

### BRIEF DESCRIPTION OF THE DRAWINGS

FIG. 1 shows an exemplary heat spreader.

FIGS. 2A and 2B show exemplary structures for guiding liquid flow motion within chambers of heat spreaders.

FIG. 3 is a graph illustrating near uniform performance of the heat spreader of FIG. 1 for different orientations with respect to gravity.

FIGS. 4A-4B depicts the heat spreader's independence to orientation with respect to gravity.

FIGS. 5A-5C show another exemplary heat spreader.

FIG. 6 is a chart illustrating the performance of the heat spreader over various operating temperatures.

FIG. 7 is a chart illustrating an exemplary performance of the heat spreader with and without a thermally-conductive micro-porous coating (TCMC) coating.

FIG. 8 is a chart illustrating an exemplary performance of the heat spreader with various levels of liquid in its chamber.

FIG. 9A, 9B, and 9C show various embodiments where the structure(s) may be located on the first plate, the second plate, or suspended between the two plates, respectively.

FIG. 10 shows yet another aspect where the first plate is replaced with the heat source surface itself.

### SUMMARY

In one aspect, a heat spreader is provided to cool a device. The heat spreader has first and second proximal opposing surfaces defining a housing, chamber, container, or vessel having a liquid therein; and one or more structures mounted in the chamber to induce a liquid flow pattern during a boiling of the liquid to distribute heat.

Implementations of the above aspect can include one or more of the following. The proximal opposing surfaces have a gap between 0.1 millimeter and 3.5 millimeters between the first and second surfaces. Each surface can be one face or side of a plate. The plate can be rigid. One surface can be one side of a plate and the other surface can be in thermal contact with various heat generating devices. The device can be a flip-chip die with a plate positioned opposite to the flip-chip die, and wherein the flip-chip die and the plate define the chamber. The device may also be a flip-chip die with a circumferential plate extending the plane of the die with a second plate positioned opposite to the flip-chip die and accompanying circumferential plate. The one or more structures can be mounted on at least one of the opposing surfaces or can be mounted between the opposing surfaces. The first surface thermally contacts the device with one or more structures mounted on the first surface internal to the chamber. Alternatively, the one or more structures can be mounted on the second surface that does not directly contact the device. The first and second opposing surfaces are separated by a small gap. The first and second opposing surface have a first separation distance above a predetermined region on device and a second separation distance surrounding the predetermined region and wherein the second separation distance is larger than the first separation distance. Alternatively, the first and second opposing surfaces can have a uniform separation distance. The liquid flow pattern is induced by bubble pumping. In one embodiment, the bubble pumping can be formed through Taylor instability of condensate when horizontally placed with the surface at a predetermined position so a heated surface faces vapor space inside the chamber. In other embodiments, the bubbling is initiated without the aid of Taylor instability and is more related omni-directional operation capability. The liquid flow pattern including bubbles guided with internal structures improves nucleate boiling heat transfer efficiency and also reduces localized dryout behavior by supplying liquid and removing vapor from a heated area. One surface can transfer heat from the device to boil the liquid. The liquid can be water, acetone, ethanol, methanol, refrigerant, and mixtures thereof, or any other working liquid with suitable properties such as boiling point and heat of vaporization. The liquid may contain nanoparticles. The liquid can be selected to boil at a predetermined pressure and temperature to match a predetermined thermal requirement of the device. The structure can be a fin structure or a rib structure, among others. Each structure can be an elongated bar and the one or more structures are placed adjacent a locally heated area. Each structure can be an elongated bar and the one or more structures can be spaced apart to surround a locally heated area. The locally heated area is centrally positioned to the one or more structures, or the locally heated area is positioned closer to one structure than another structure. A coating can be formed on the surface. The surface can be a sintered surface, a machined surface, an etched surface, a micro-porous coating, or a thermally-conductive micro-porous coating (TCMC). A gap between 0.1 and 3.5 millimeters can be provided between the coating and the opposite surface. The coating can be formed in one of: a recessed area, a flat area, an extruded area. The surface can be formed using stamping. The one or more structures can be formed using one of: placing wires, placing ribs, shaping ribs, etching ribs, stamping ribs, or machining ribs. The gap between the first and second surfaces can be less than 3.5 millimeters. The gap between the first and second surfaces can also be between 0.1 millimeter and 3.5 millimeters. The gap between the first and second surfaces can be about 0.1 mm, 1 mm, 1.5 mm, 2 mm, 3 mm, and 3.5 mm. A heat sink or cold plate can be attached to one of the surfaces. Alternatively, the heat spreader can be attached to or embedded in the base of heat sink unit. In this case, base surface of heat sink can serve as one surface.

In a second aspect, systems and fabrication methods are disclosed for a heat spreader to cool a device. The heat spreader has a first plate thermally coupled to the device; and a second plate coupled to the first plate to form a chamber, container or vessel for housing a liquid, the second plate having one or more structures mounted thereon to induce a liquid flow pattern.

Implementations of the second aspect can include one or more of the following. The one or more structures can be attached to the first plate, the second plate or can be suspended between the first and second plates. The pattern in the liquid flow is induced by bubble pumping. The bubble pumping is formed through bubbles produced due to nucleate boiling at the base plate where heat is transmitted from heat generating devices. The bubble-pumped liquid flow provides strong circulating flow motion that promote the nucleate boiling heat transfer and also prevents formation of a localized vapor dryout zone at the boiling surface. The first plate provides heat to boil the liquid. The liquid can be chosen for specific requirement and can be water, ethanol, fluorocarbon liquid, methanol, acetone, refrigerant, or any other working liquid with suitable properties such as boiling point and heat of vaporization, for example. A mixture of two or multiple liquids can be also used. The structure can be a fin structure or a rib structure. Each structure can be an elongated bar and the structures can be placed adjacent (centrally or offset from the center) a locally heated area. The structures can be spaced apart to surround (centrally or offset from the center) a locally heated area. The locally heated area can be centrally positioned to the one or more structures or can be positioned closer to one structure than another structure. A coating can be formed on the first plate, and the coating can be a micro-porous coating, or can be a TCMC or other boiling enhancing surfaces. A gap between 0.1 and 3.5 millimeters can be formed between the first and the second plate. The first plate can have a recessed area or a flat area. The first plate can be formed using stamping, while the structures on the first or second plate can be formed using stamping or machining. Structures can be also detached from the two plates and simply inserted and fixed in the middle of the two plates. Any shape (wire, rectangle, I-beam, U-beam, etc.) can be used as long as the gap can be created by them. A gap of approximately 0.1 to approximately 3.5 millimeters can be formed between the first and second plates. Form factors other than the thin flat plate can be developed, including 3D shapes and volumes. Additionally, the plate can be a part of an assembly such as fins, for example.

Advantages of the invention may include one or more of the following. The system replaces a conventional solid-block heat spreading unit with a low-profile chamber containing liquid. During operation, the device being cooled boils the liquid, and the liquid boiling is combined with a thin chamber or gap to create the bubble pumping action to induce a streamlined flow pattern that enhances the cooling effects. Additionally, the thin gap allows freedom of orientation with respect to gravity. The system uses nucleate boiling and condensation in a thin circular, square, or rectangular form for the heat spreading. The internal structures promote the streamlined flow pattern induced by nucleate boiling. The structures also provide mechanical strength that prevents bending of the plate and any assembly or parts built thereon. Further enhancement of heat spreader performance can be achieved by employing different surface treatments for boiling heat transfer. The total thickness of the hollow heat spreader can be as low as about 0.1 millimeter, providing weight reduction from conventional solid heat spreaders. The heat spreader cools the device through the boiling of the liquid and through the induced liquid flow pattern, and achieves cooling without requiring an external pump. The pumping power comes from the motion of bubbles due to buoyancy after they depart the boiling surface, which provides a strong liquid pumping power and heat spreading capability and thus provides excellent omni-directional performance that is relatively insensitive to direction and orientation of the heat spreader.

### DESCRIPTION

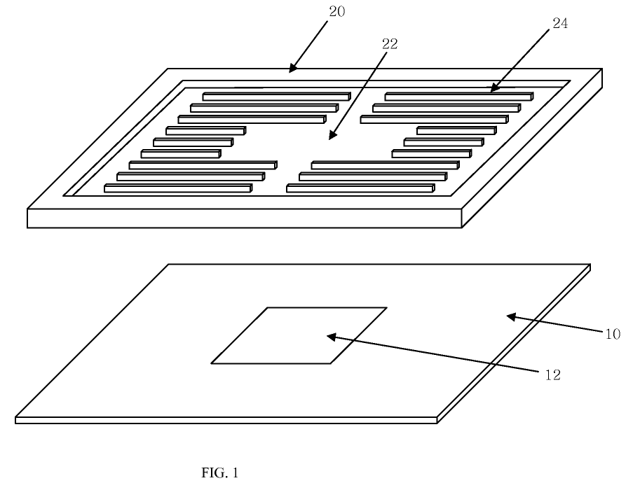

Referring now to FIG. 1, a heat spreader in accordance with one aspect of the invention is shown. The heat spreader has a base or first plate 10 that engages a top or second plate 20. The first plate 10 is adapted to be in thermal contact with a heat generating device such as a processor or graphics device, for example. In one embodiment, the first plate is a thin plate with a locally heated region that is thermally in contact with the heat generating device. The first plate can have a recessed portion, or can be completely flat.

In combination, the first and second plates 10 and 20 form housing or chamber that stores a liquid. The liquid can be boiled when the first plate 10 is heated by the heat generating device, and the boiling action cools the heat generating device during its operation.

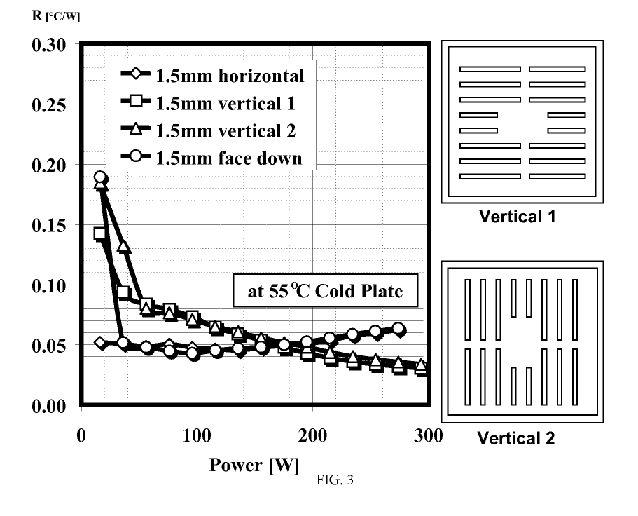

The second plate 20 has a plurality of structures 24 that project toward the first plate 10. The structures 24 can be a series of barriers, ribs, or fins that can guide liquid flow motion within the chamber. The liquid flow is enhanced by a bubble pumping action that will be discussed in more detail below with respect to FIGS. 3A and 3B.

To increase boiling heat transfer performance that is used also in the current heat spreaders, surface enhancement techniques have been investigated by researchers to augment nucleate boiling heat transfer coefficient and to extend the critical heat flux (CHF, or the highest heat flux that can be removed without exposing the surface to film boiling), and the techniques have been commercialized to maximize boiling heat transfer performance. Commercial surfaces for boiling enhancement include different types of cavities or grooves such as Furukawa's ECR-40, Wieland's GEWA, Union Carbide's High-Flux, Hitachi's Thermoexcel, and Wolverine's Turbo-B. The surface enhancement techniques are to increase vapor/gas entrapment volume and thus to increase active nucleation site density.

In one implementation, the first plate has an enhanced boiling surface microstructure such as microporous surface structures. The microporous coating (MC) provides a significant enhancement of nucleate boiling heat transfer and CUE while reducing incipient wall superheat hysteresis. One option of the microporous coating is ABM coating technique developed by You and O'Connor (1998) (U.S. Pat. No. 5,814,392). The coating is named from the initial letters of their three components (Aluminum/Devcon Brushable Ceramic/Methyl-Ethyl-Keytone). After the carrier (M.E.K.) evaporates, the resulting coated layer consists of microporous structures with aluminum particles (1 to 20 μm) and a glue (Omegabond 101 or Devcon Brushable Ceramic) having a thickness of 50 μm, which was shown as an optimum thickness for FC-72. The boiling heat transfer advantages of the non-conducting microporous coating method can be improved by replacing the thermally non-conducting glue with a thermally conducting binder. More details of MC are disclosed in U.S. Pat. No. 5,814,392, the content of which is incorporated by reference.

In another implementation, the first plate has a Thermally-Conductive Microporous Coating (TCMC). The TCMC or any suitable coatings are used to enhance nucleate boiling heat transfer performance and extend the heat flux limitation of nucleate boiling capability (Critical Heat Flux). The enhanced performance of microporous coatings results from an increase in the number of active nucleation sites. Higher bubble departure frequency from boiling site decreases the thickness of the superheated liquid layer, inducing the increase in micro-convection heat transfer. TCMC is described in more details in commonly assigned, co-pending patent application having Ser. No. 11/272,332, the content of which is incorporated by reference.

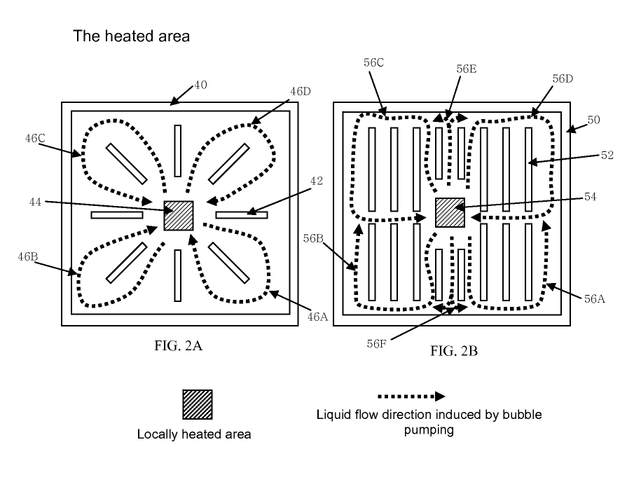

Turning now to FIGS. 2A and 2B, exemplary structures for guiding liquid flow motion within chambers of heat spreaders are detailed. FIG. 2A shows a second plate 40 with a clock-like arrangement where members 42 are centrally positioned around a locally heated region 44. The members 42 guide liquid flow in patterns 46A-46D as induced by bubble pumping actions. Correspondingly, FIG. 2B shows a second plate 50 with a fin arrangement where fins 52 are centrally positioned around a locally heated region 54. The members 52 guide liquid flow in patterns 56A-56D and 56E-56F as induced by bubble pumping actions. The direction of liquid flow is important in maximizing heat removal through the liquid flow, and FIGS. 2A-2B illustrate that liquid motion is directed to ensure maximum efficiency for the removal of heat from the locally heated regions 44 and 54, respectively.

FIG. 3 is a graph illustrating the performance of the heat spreader of FIG. 1 to be independent of orientation with respect to gravity. The heat spreader can be placed vertically, horizontally, or face down (upside down) where the liquid is below the locally heated region. As shown therein, the heat spreader provides excellent heat removal capability with a uniform temperature over entire surface (difference of ˜1° C.), regardless of orientation. Hence, the performance of the heat spreader is independent of orientation. When placed horizontally, the face up (liquid above the coating) and face down (liquid below the coating) configurations show identical performance. The horizontal configurations show better performance up to about 180 W, while the vertical configurations outperform after about 180 W due to faster re-wetting assisted by gravity.

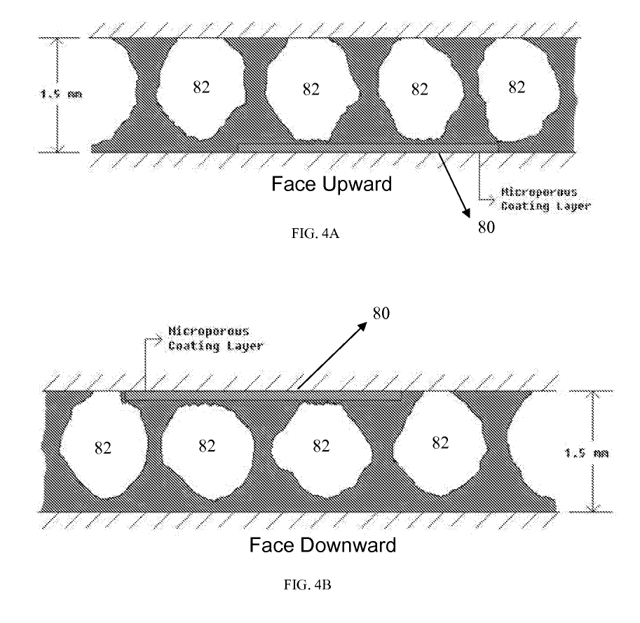

FIGS. 4A-4B depicts the heat spreader's orientation independent performance in two horizontal test configurations. In FIG. 4A, the coating faces horizontally upward, while in FIG. 4B, the coating faces horizontally downward. In either case, the same pattern of liquid columns 82 exist before heat is applied. Since the chamber is kept in thermodynamically saturated state, evaporation and condensation continue to occur inside of the chamber. The condensate has to return to the lower position by the gravity after forming liquid drops. Due to the surface tension and Taylor instability of the condensed liquid, water liquid columns are formed. This effect is especially pronounced when the gap between the two plates is between 0.1 to 3.5 millimeters. Once the boiling occurs by heating in horizontal downward configuration, the initial nucleation occurs in the columns of liquid or absorbed liquid in the microporous structures where heat is applied, followed by bubble pumping. This unique nucleate boiling initiation makes the bulk of liquid boil regardless of direction. Continuous and stable bulk fluid nucleate boiling causes much stronger and established bubble-pumped flow circulation pattern promoting heat speading efficiency. Therefore, in the horizontal cases regardless of facing up or down, the bubble-pumped nucleate boiling heat transfer dominates the heat transfer whether the coatings are positioned face up or face down.

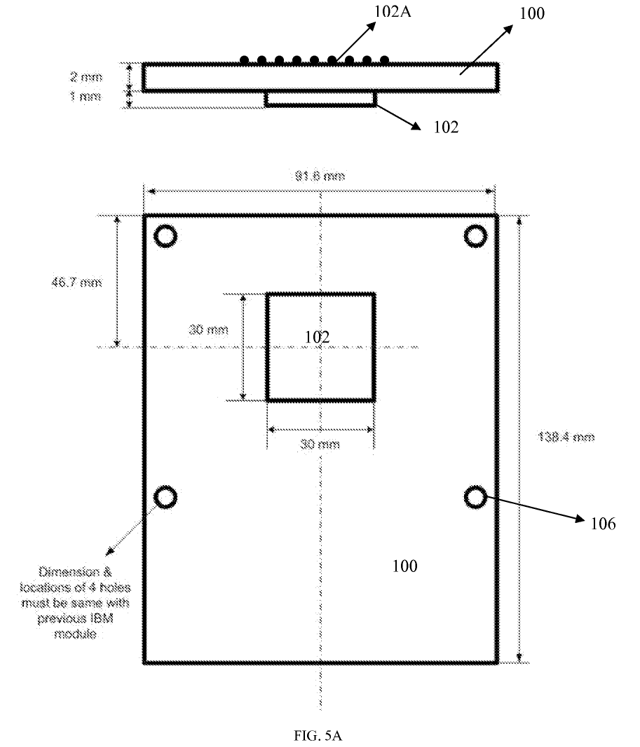

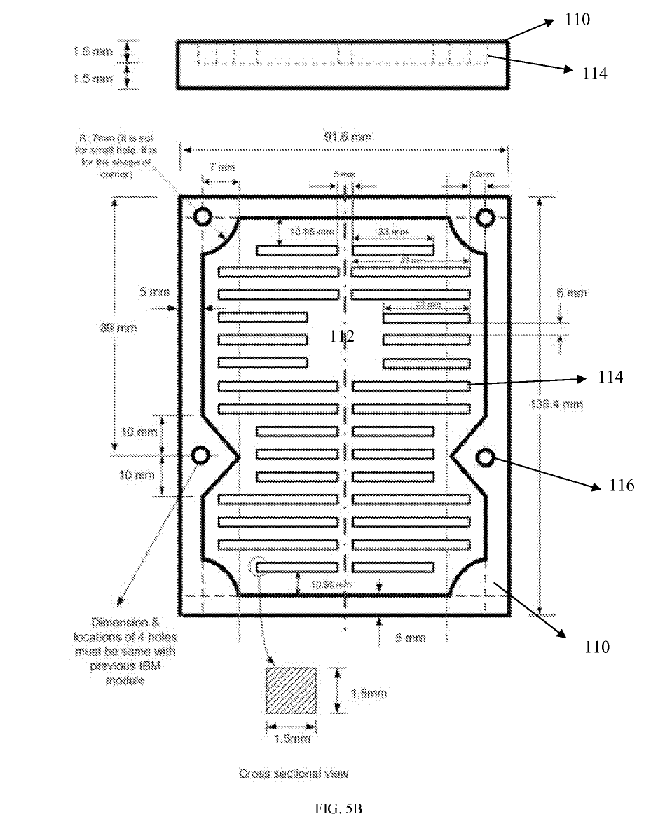

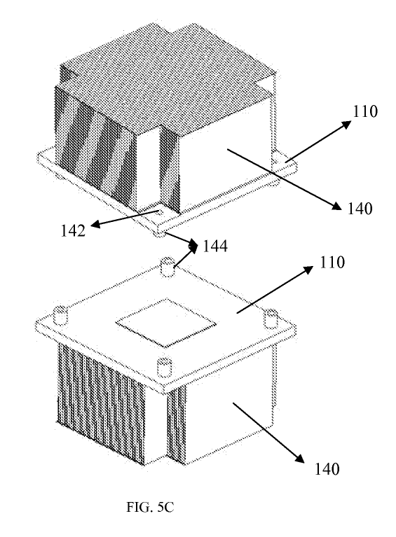

FIGS. 5A-5B and FIG. 5C show additional exemplary heat spreader embodiments. In FIG. 5A, a base plate 100 has a coating on the other flat side of 102 such as a TCMC coating above the locally heated region. A based 102 can be provided as a piece of metal (or thicker metal on the same plate) that helps spreading heat from the heat source to the coating. This is particularly helpful when the heat source is small, because this will ‘spread’ heat from the heat source to the wider area defined by the heat spreader to provide a wider effective coating area that works as the nucleation sites and helps bubble pumping action.

Four holes are positioned on the base plate 100 to secure the base plate to a heat sink (not shown). FIG. 5B shows a corresponding top plate 110 having a region 112 that is directly above the coating 102A. Also, fins 114 are positioned around the region 112 to encourage bubble pumping actions that drive liquid in one or more predetermined directions within a chamber formed when the base plate 100 engages the top plate 110. In this embodiment, the fins 114 are not equidistant with the heated region 112 as the fins are not concentrically (or centrally) placed around the region 112. However, in other embodiments such as those of FIGS. 2A-2B, the fins 42 and 52 are symmetrically formed and have the heated regions 44 and 54 at the center.

FIG. 5C shows an exemplary heat sink constructed by attaching fins 140 positioned above the top plate 110. The fins 140 are secured to the assembly of the top plate 110 by various means including but not limited to soldering, brazing, mechanical compression and chemical bonding. The fins 140 enable heat captured by the heat spreader of FIGS. 5A-5B to be dissipated into ambient air.

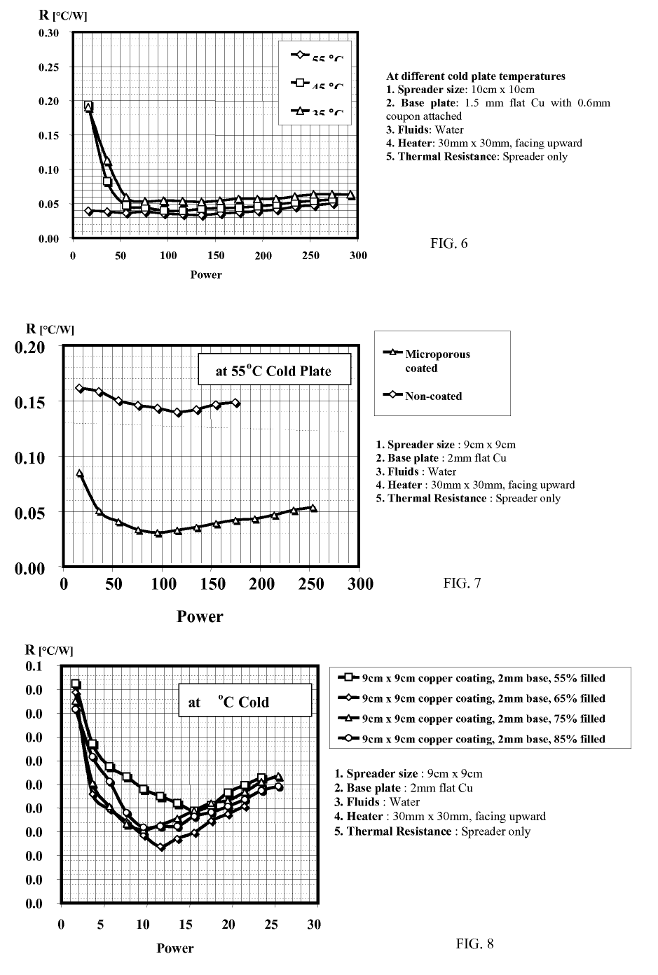

FIG. 6 is a chart illustrating the performance of the heat spreader over various operating temperatures. As shown therein, the performance of the heat spreader with the TCMC enhances slightly as the operating temperature increases. This is due to the pressure effect on nucleate boiling heat transfer. As shown in FIG. 6, active boiling is promoted at higher temperatures.

FIG. 7 is a chart illustrating the performance of the heat spreader with and without the TCMC coating. As shown therein, the micro-porous coating augments the thermal performance of thin spreader significantly (by the factor of about three) because of nucleate boiling enhancement effects.

FIG. 8 is a chart illustrating the performance of the heat spreader with various amounts of liquid in its chamber. FIG. 8 shows that the optimum liquid filling ratio is about 65% at the given geometry of 9 cm×9 cm with 1.5 mm internal chamber gap using water as the filling liquid. The ratio can vary with different orientation, geometry, and heating element size, and thus optimization can be arrived at using an iterative process.

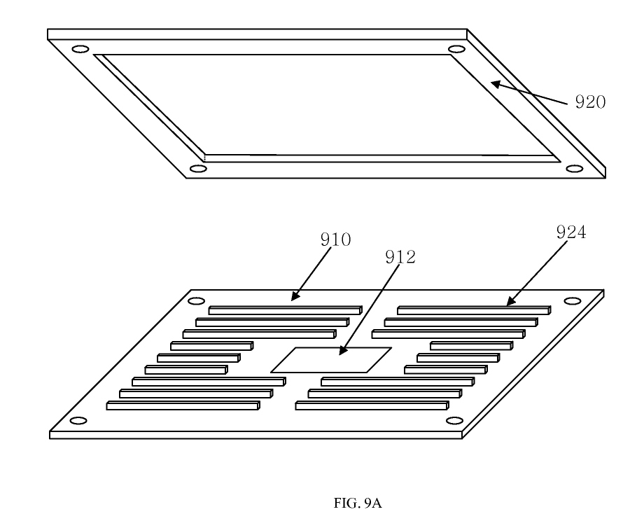

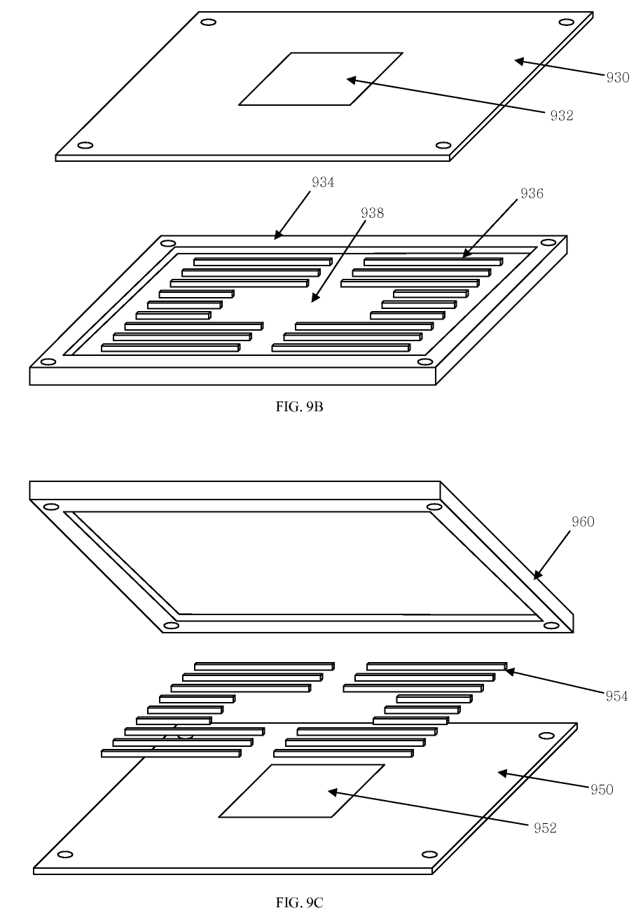

FIGS. 9A, 9B, and 9C show various embodiments where the structure(s) may be located on the first plate, the second plate, or between both, respectively. Turning now to FIG. 9A, a heat spreader where structures 924 are formed on the first plate 910 is shown. The first plate 910 is thermally coupled to the heat generating device through a coated region 912. A second plate 920 is then secured to the first plate 910 and a liquid is introduced into the chamber formed by plates 910 and 920.

FIG. 9B shows an embodiment where the structure is positioned on a second plate 934 with structures 936 (such as ribs or bars) surrounding a heated region 938. Correspondingly, a first plate 930 is in thermal contact with the device through a coated region 932.

FIG. 9C shows an embodiment where the structures 954 are suspended between the first and second plates 950 and 960, respectively. The first plate 950 is thermally coupled to the device through a coated region 952 which can be TCMC, among others.

The one or more structures can be attached to the first plate, the second plate or can be suspended between the first and second plates. The pattern in the liquid flow is induced by bubble pumping. The bubble pumping is formed through bubbles produced due to nucleate boiling at the base plate where heat is transmitted from heat generating devices. The bubble-pumped liquid flow provides a strong circulating flow motion that promotes the nucleate boiling heat transfer and also prevents the formation of a localized vapor dryout zone at the boiling surface. The first plate provides heat to boil the liquid. The liquid can be chosen for specific requirement and can be water, ethanol, fluorocarbon liquid, methanol, acetone, refrigerant, or any other working liquid with suitable properties such as boiling point and heat of vaporization, for example. A mixture of two or multiple liquids can be also used. The structure can be a fin structure or a rib structure. Each structure can be an elongated bar and the structures can be placed adjacent (centrally or offset from the center) a locally heated area. The structures can be spaced apart to surround (centrally or offset from the center) a locally heated area. The locally heated area can be centrally positioned to the one or more structures or can be positioned closer to one structure than another structure. A coating can be formed on the first plate, and the coating can be a micro-porous coating, or can be a TCMC or other boiling enhancing surfaces. A gap between 0.1 and 3.5 millimeters can be formed between the first and the second plate. The first plate can have a recessed area, an extruded area or a flat area. The first plate can be formed using stamping, while the structures on the first or second plate can be formed using stamping or machining. Structures can be also detached from the two plates and simply inserted and fixed in the middle of the two plates. Any shape (wire, rectangle, I-beam, U-beam, etc.) can be used as long as the gap can be created by them. A gap of approximately 0.1 to approximately 3.5 millimeters can be formed between the first and second plates. Form factors other than the thin flat plate can be developed, including 3D shapes and volumes. Additionally, the plate can be a part of an assembly such as fins, for example.

The system of FIGS. 9A-9C replaces a conventional solid-block heat spreading unit with a low-profile chamber containing liquid. During operation, the device being cooled boils the liquid, and the liquid boiling is combined with a thin chamber or gap to create the bubble pumping action to induce a recirculating flow pattern that enhances the cooling effects. Additionally, the thin gap allows orientation-free operation with respect to gravity. The system uses nucleate boiling and condensation in a thin circular, square, or rectangular form for the heat spreading. The internal structures promote the streamlined flow pattern induced by nucleate boiling. The structures also provide mechanical strength that prevents bending of the plate and any assembly or parts built thereon. Further enhancement of heat spreader performance can be achieved by employing different surface treatments for boiling heat transfer. The total thickness of the hollow heat spreader can be as low as about 0.1 millimeter, providing weight reduction from conventional solid heat spreaders. The heat spreader cools the device through the boiling of the liquid and through the induced liquid flow pattern, and achieves cooling without requiring an external pump. The strong pumping power from bubble formation on boiling surface and bubble departure and buoyancy provides excellent omni-directional performance that is relatively insensitive to direction and orientation of the heat spreader.

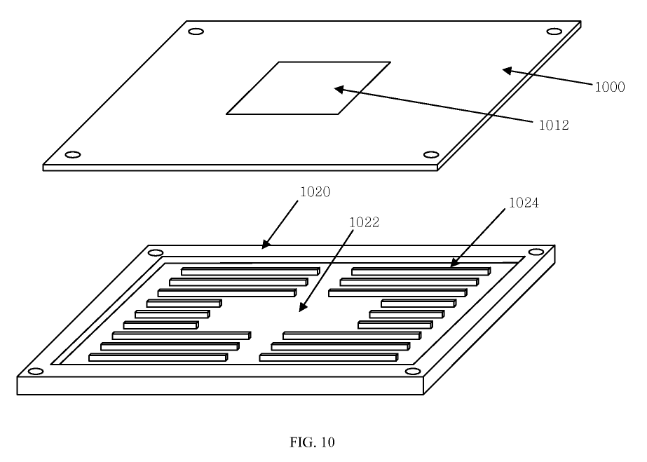

FIG. 10 shows yet another aspect where the first plate 1000 or a portion of the first plate 1000 is replaced with the heat source device itself This would be particularly relevant where the chamber becomes a part of semiconductor packaging where the boiling enhancement is placed directly on the back side of an IC die 1012, and the cavity formed by the die 1012 and a second plate 1020 with structures 1024 formed thereon to define the chamber itself. The second plate has a heated region 1022 to optimize the liquid flow pattern to remove heat.

The arrangement of FIG. 10 is thin and can be used to cool flip-chip dies. Flip-chips have been developed to satisfy the electronic industry's continual drive to lower cost, to increase the packaging density and to improve the performance while still maintaining or even improving the reliability of the circuits. In the flip-chip manufacturing process, a semiconductor chip is assembled face down onto circuit board. This is ideal for size considerations, because there is no extra area needed for contacting on the sides of the component (true also with TAB). The performance in high frequency applications is superior to other interconnection methods, because the length of the connection path is minimized. Flip chip technology is cheaper than wire bonding (true also with TAB) because bonding of all connections takes place simultaneously whereas with wire bonding one connection is made at a time. There are many different alternative processes used for flip-chip joining. A common feature of the joined structures is that the chip is lying face down to the substrate and the connections between the chip and the substrate are made using bumps of electrically conducting material.

While flip-chips have certain size and cost advantages, due to their compact size, they have limited heat dissipation capability. Integrated circuits such as microprocessors (CPUs) and graphics processing units (GPUs) generate heat when they operate and frequently this heat must be dissipated or removed from the integrated circuit die to prevent overheating. The system of FIG. 10 ensures that the heat absorbing surface or coating contacts the liquid coolant to ensure an efficient transfer of heat from the heat source to the liquid and to the rest of the module. The system allows the integrated circuit to run at top performance while minimizing the risk of failure due to overheating. The system provides a boiling cooler with a vessel in a simplified design using inexpensive non-metal material or low cost liquid coolant in combination with a boiling enhancement surface or coating.

While the present invention has been described with reference to particular figures and embodiments, it should be understood that the description is for illustration only and should not be taken as limiting the scope of the invention. Many changes and modifications may be made to the invention, by one having ordinary skill in the art, without departing from the spirit and scope of the invention. For example, additional heat sink or fins or other dissipation layers may be added to enhance heat dissipation of the integrated circuit device. Additionally, various packaging types and IC mounting configurations may be used, for example, ball grid array, pin grid array, etc. Furthermore, although the invention has been described in a particular configurations and orientations, words like “above,” “below,” “overlying,” “beneath,” “up,” “down,” “height,” etc. should not be construed to require any absolute configuration or orientation. Other variations and embodiments are possible in light of above teachings, and it is thus intended that the scope of invention not be limited by the description, but rather by the following claims.

What is claimed is:

1. A heat spreader to cool a device, comprising:
first and second opposing proximal surfaces defining a chamber containing a liquid therein; and
one or more structures mounted in the chamber to induce a liquid flow pattern during boiling of the liquid to cool the device.

2. The heat spreader of claim 1, wherein each surface comprises a plate.

3. The heat spreader of claim 2, wherein the plate is rigid.

4. The heat spreader of claim 1, wherein one surface comprises one side of a plate and the other surface contacts the device.

5. The heat spreader of claim 1, wherein the device comprises a flip-chip die, comprising a plate positioned opposite to the flip-chip die, wherein the flip-chip die and the plate define the chamber.

6. The heat spreader of claim 5, wherein the device composes a flip-chip die with a circumferential plate, comprising a plate positioned opposite to the flip chip die with circumferential plate, wherein the flip-chip die with circumferential plate and the opposing plate define the chamber.

7. The heat spreader of claim 5, wherein the device composes a flip-chip die with an adjoining plate, comprising a plate positioned opposite to the flip-chip die with adjoining plate, wherein the flip-chip die with adjoining plate and the opposing plate define the chamber.

8. The heat spreader of claim 1, wherein the one or more structures are mounted on at least one of the opposing surfaces.

9. The heat spreader of claim 1, wherein the one or more structures are mounted between the opposing surfaces.

10. The heat spreader of claim 1, wherein the first surface thermally contacts the device and wherein the one or more structures are mounted on the first surface.

11. The heat spreader of claim 1, wherein the first surface thermally contacts the device and wherein the one or more structures are mounted on the second surface.

12. The heat spreader of claim 1, wherein the first and second opposing surfaces are separated by a small gap.

13. The heat spreader of claim 1, wherein the first and second opposing surface have a first separation distance above a predetermined region on device and a second separation distance surrounding the predetermined region and wherein the second separation distance is larger than the first separation distance.

14. The heat spreader of claim 1, wherein the first and second opposing surface have a uniform separation distance.

15. The heat spreader of claim 1, wherein the liquid flow pattern is induced by bubble pumping.

16. The heat spreader of claim 15, wherein the bubble pumping is formed through Taylor instability of condensate when horizontally placed with the surface at a predetermined position so a heated surface faces vapor space inside the chamber.

17. The heat spreader of claim 1, wherein the liquid flow pattern improves nucleate boiling heat transfer and also removes locally generated vapor dryout zone at a heated area.

18. The heat spreader of claim 1, wherein one surface transfers heat to boil the liquid.

19. The heat spreader of claim 1, wherein the liquid comprises one of: water, acetone, ethanol, methanol, refrigerant, and mixtures thereof.

20. The heat spreader of claim 1, wherein the liquid contains nanoparticles.

21. The heat spreader of claim 1, wherein the liquid is selected to boil at a predetermined temperature to match a predetermined thermal requirement of the device.

22. The heat spreader of claim 1, wherein the structure comprises one of: a fin structure, a rib structure.

23. The heat spreader of claim 1, wherein each structure comprises an elongated bar and the one or more structures are placed adjacent a locally heated area.

24. The heat spreader of claim 1, wherein each structure comprises an elongated bar and the one or more structures are spaced apart to surround a locally heated area.

25. The heat spreader of claim 24, wherein the locally heated area is centrally positioned to the one or more structures.

26. The heat spreader of claim 24, wherein the locally heated area is positioned closer to one structure than another structure.

27. The heat spreader of claim 1, comprising a coating formed on the surface.

28. The heat spreader of claim 1, wherein the surface comprises one of: a sintered surface, a machined surface, a micro-porous coating, a thermally-conductive micro-porous coating (TCMC).

29. The heat spreader of claim 36, comprising a gap between 0.1 and three millimeters between the coating and the surface facing the coating.

30. The heat spreader of claim 1, wherein the surface comprises a coating formed in one of: a recessed area, a flat area, an extruded area.

31. The heat spreader of claim 1, wherein the surface is formed using stamping.

32. The heat spreader of claim 1, wherein the one or more structures are formed using one of: placing wires, placing ribs, shaping ribs, stamping ribs, machining ribs.

33. The heat spreader of claim 1, comprising a gap of less than 3.5 millimeters between the first and second surfaces.

34. The heat spreader of claim 1, comprising a gap between 0.1 millimeter and 3.5 millimeters between the first and second surfaces.

35. The heat spreader of claim 1, comprising a gap selected from a group consisting of about 0.1 mm, 1 mm, 1.5 mm, 2 mm, 3 mm, and 3.5 mm between the first and second surfaces.

36. The heat spreader of claim 1, comprising a heat sink or cold plate coupled to one of the surfaces.

37. The heat spreader of claim 1, comprising one or more fins coupled to one of the surfaces.

38. The heat spreader of claim 1, wherein the one or more structures provide mechanical support for the chamber.

39. The heat spreader of claim 1, wherein the surfaces comprise 3D shapes or volumes.
